(19) United States
(12) Patent Application Publication
(10) Pub. No.: US 2016/0043137 A1
(43) Pub. Date: Feb. 11, 2016

(54) RESISTIVE MEMORY DEVICE WITH ZERO-TRANSISTOR, ONE-RESISTOR BIT CELLS INTEGRATED WITH ONE-TRANSISTOR, ONE-RESISTOR BIT CELLS ON A DIE

(71) Applicant: QUALCOMM Incorporated, San Diego, CA (US)

(72) Inventors: Yu LU, San Diego, CA (US); Seung Hyuk KANG, San Diego, CA (US)

(21) Appl. No.: 14/454,821

(22) Filed: Aug. 8, 2014

(51) Int. Cl. H01L 27/24; H01L 43/12; G11C 11/16; H01L 27/22; H01L 43/02; G11C 13/00; H01L 45/00; H01L 43/08

(52) U.S. Cl. CPC H01L 27/2436; H01L 45/06; H01L 43/12; H01L 43/08; H01L 27/228; H01L 45/16; H01L 43/02; G11C 13/0069; G11C 11/1675

(57) ABSTRACT

A resistive memory array includes an array of one-transistor, one-resistor (1T1R) bit cells on a die. The resistive memory array also includes an array of zero-transistor, one-resistor (0T1R) bit cells arranged with the array of 1T1R bit cells on the same die.

### TECHNICAL FIELD

The present disclosure generally relates to resistive memories. More specifically, the present disclosure relates to a resistive memory device with zero-transistor, one-resistor (0T1R) bit cells integrated with one-transistor, one-resistor (1T1R) bit cells on a die.

### BACKGROUND

Semiconductor devices use many different types of memories to achieve performance, power, cost and data retention specifications. For example, unlike conventional semiconductor random access memory (RAM) chip technologies, in magnetic RAM (MRAM) data is stored by magnetization of storage elements. The basic structure of the storage elements consists of metallic ferromagnetic layers separated by a thin tunneling barrier. The ferromagnetic layers on one side of the barrier (e.g., the pinned layer) have a magnetization that is fixed in a particular direction. The ferromagnetic magnetic layers on the opposite side of the tunneling barrier (e.g., the free layer) have a magnetization direction that may be altered to represent either a “1” or a “0.” For example, a “1” may be represented when the free layer magnetization is anti-parallel to the fixed layer magnetization. In addition, a “0” may be represented when the free layer magnetization is parallel to the fixed layer magnetization or vice versa.

One such device having a fixed layer, a tunneling layer, and a free layer is a magnetic tunnel junction (MTJ). The electrical resistance of an MTJ depends on whether the free layer magnetization and fixed layer magnetization are parallel or anti-parallel to each other. A memory device such as MRAM is built from an array of individually addressable MTJs.

In one particular method for writing data in a conventional MRAM, a write current, which exceeds a critical switching current, is applied through an MTJ. Application of a write current that exceeds the critical switching current changes the magnetization direction of the free layer. When the write current flows in a first direction, the MTJ may be placed into or remain in a first state in which its free layer magnetization direction and fixed layer magnetization direction are aligned in a parallel orientation. When the write current flows in a second direction, opposite to the first direction, the MTJ may be placed into or remain in a second state in which its free layer magnetization and fixed layer magnetization are in an anti-parallel orientation.

To read data in a conventional MRAM, a read current may flow through the MTJ via the same current path used to write data in the MTJ. If the magnetizations of the MTJ's free layer and fixed layer are oriented parallel to each other, the MTJ presents a parallel resistance. The parallel resistance is different than a resistance (anti-parallel) the MTJ would present if the magnetizations of the free layer and the fixed layer were in an anti-parallel orientation. In a conventional MRAM, two distinct states are defined by these two different resistances of an MTJ in a bit cell of the MRAM. The two different resistances indicate whether a logic “0” or a logic “1” value is stored by the MTJ.

Spin-transfer-torque magnetic random access memory (STT-MRAM) is an emerging nonvolatile memory that has advantages of non-volatility. In particular, STT-MRAMs built on processor chips may operate at a higher speed than off-chip dynamic random access memory (DRAM). In addition, STT-MRAM has a smaller chip size than embedded static random access memory (eSRAM), unlimited read/write endurance, and a low array leakage current. Perpendicular magnetic tunnel junctions (pMTJs) may be one type of MTJ element within a STT-MRAM.

A “universal memory” applicable to all devices has long been a goal of emerging memory technologies, including resistive memory, non-volatile memory, or other like emerging memory technologies. Resistive memory technologies other than MRAM and STT-MRAM may include, but are not limited to, phase change memory (PCM) technology, such as a phase change random access memory (PCRAM), and resistive random access memory (RRAM).

### SUMMARY

A resistive memory array may include an array of one-transistor, one-resistor (1T1R) bit cells on a die. The resistive memory array may also include an array of zero-transistor, one-resistor (0T1R) bit cells arranged with the array of 1T1R bit cells on the same die.

A method of storing data within a resistive memory array may include storing a first copy of critical data within an array of one-transistor, one-resistor (1T1R) bit cells. This method also includes storing a second copy of critical data within an array of zero-transistor, one-resistor (0T1R) bit cells arranged with the array of 1T1R bit cells on a same die.

In another aspect, a method of storing data within a resistive memory array includes caching data within an array of one-transistor, one resistor (1T1R) bit cells for an array of zero-transistor, one-resistor (0T1R) bit cells arranged with the array of 1T1R bit cells on a same die.

In another aspect, a method of manufacturing a hybrid resistive memory array includes fabricating an array of one-transistor, one-resistor (1T1R) bit cells on a die. The method also includes fabricating an array of zero-transistor, one-resistor (0T1R) bit cells arranged with the array of 1T1R bit cells on the same die.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a diagram of a magnetic tunnel junction (MTJ) device connected to an access transistor.

FIG. 2 is a conceptual diagram of a conventional magnetic random access memory (MRAM) cell including an MTJ.

FIG. 3A is a schematic view of a one-transistor, one-resistor (1T1R) bit cell according to aspects of the present disclosure.

FIG. 3B is a schematic view of a zero-transistor, one-resistor (0T1R) bit cell according to aspects of the present disclosure.

FIG. 3C is a three dimensional view of a resistive memory device according to aspects of the present disclosure.

FIG. 4 is a schematic view of a resistive memory device according to aspects of the present disclosure

FIG. 5 is a layout view of a resistive memory device according to aspects of the present disclosure.

FIG. 6 is a cross-sectional view of a resistive memory device according to aspects of the present disclosure.

FIG. 7 is a process flow diagram illustrating a method of storing data within a resistive memory array according to aspects of the present disclosure.

FIG. 8 is a block diagram showing an exemplary wireless communication system in which a configuration of the disclosure may be advantageously employed.

FIG. 9 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Emerging resistive memories may include magnetic random access memories (MRAMs), phase change memories (PCM), resistive RAM (RRAM), spin transfer torque magnetoresistive random access memories (STT-MRAM) and other similar memory technologies. It is to be understood that the phrase “resistive memory” in this disclosure is to include all memory technologies where digital data is stored in a resistor having multiple resistance states, and should not be interpreted to be resistive RAM or RRAM. These emerging resistive memory technologies, including a resistive memory array architecture, may be integrated at the interconnect level. There are two general options for implementing a resistive memory array architecture: (1) one-transistor, one-resistor (1T1R) bit cells; and (2) zero-transistor, one-resistor (0T1R) bit cells. The said 0T1R bit cell may also include thin-film diode or other non-linear bit selection devices, as is commonly known by those skilled in the art. Although 1T1R bit cells can support high performance read and write operations, a 1T1R bit cell size is limited by the transistor size. Conversely, 0T1R bit cells can provide a density advantage that enables a higher level of device integration. Unfortunately, the use of 0T1R bit cells is limited due to an unintended electrical current path (also known as the “sneak path”) that occurs within 0T1R bit cells.

It may be possible to combine both 1T1R and 0T1R bit cells into one device or die. Unfortunately, a solution to the various issues that arise from these different design architectures should still be solved for the overall device to run smoothly and experience both the performance and density advantages of the individual 1T1R and 0T1R implementations.

According to one aspect of the present disclosure, 0T1R and 1T1R bit cells are combined by placing 0T1R bit cell arrays on the 1T1R bit cell arrays in the same semiconductor chip area, and at different interconnect levels. For example, after a STT-MRAM array using 1T1R bitcell has been fabricated on the chip, 0T1R array or arrays of RRAM can be fabricated at higher interconnect levels. According to another aspect of the present disclosure, 0T1R and 1T1R bit cells are combined into a unified bitcell, and are built together with the same fabrication process. Because the 0T1R bit cells may be arranged within relatively small areas, they can be combined with the 1T1R bit cells without a substantial increase in the overall chip area. The resulting semiconductor device combines the merits of 0T1R and 1T1R bit cells to improve performance, increase density, save chip area and strengthen data storage security. Furthermore, the resistive devices used for the resistor in the 0T1R bit cells and the 1T1R bit cells can be configured differently to achieve performance improvement, reductions in chip area, and increased data storage security.

In one configuration, a 0T1R cross-point resistive memory array is integrated within back-end-of-line (BEOL) interconnect levels above the 1T1R resistive memory array. In this arrangement, the specified electrical coupling to semiconductor devices (e.g., transistors, diodes) are provided at the physical edges of the array block.

In one configuration, a 0T1R memory array is stacked on a 1T1R memory array. In this configuration, the 1T1R and 0T1R memory arrays can be of different resistive memory technologies, or have different resistive elements. For example, the 1T1R bit cells may be implemented with a spin transfer torque magnetoresistive random access memory (STT-MRAM), while the 0T1R bit cell may be implemented with resistive RAM (RRAM).

According to another aspect of the present disclosure, 0T1R bit cells are fabricated together with 1T1R bit cells in a particular arrangement that increases density and reduces manufacturing costs. Specifically, the 0T1R bit cell can be fabricated adjacent to the 1T1R bit cell so that density is increased for the overall resistive memory device. Furthermore, the same process can be used to fabricate both the 0T1R bit cell and the 1T1R bit cell, which in turn saves manufacturing costs.

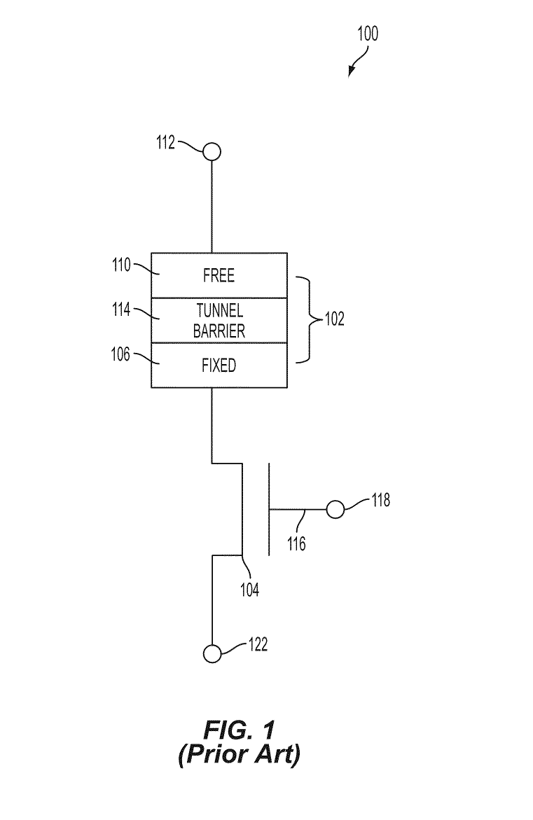

FIG. 1 illustrates a memory cell 100 of a memory device including a magnetic tunnel junction (MTJ) 102 coupled to an access transistor 104. The memory device may be a magnetic random access memory (MRAM) device that is built from an array of individually addressable MTJs. An MTJ stack may include a free layer, a fixed layer and a tunnel barrier layer there between as well as one or more ferromagnetic layers. Representatively, a free layer 110 of the MTJ 102 is coupled to a bit line 112. The access transistor 104 is coupled between a fixed layer 106 of the MTJ 102 and a fixed potential node 122. A tunnel barrier layer 114 is coupled between the fixed layer 106 and the free layer 110. The access transistor 104 includes a gate 116 coupled to a word line 118.

Synthetic anti-ferromagnetic materials may form the fixed layer 106 and the free layer 110. For example, the fixed layer 106 may comprise multiple material layers including a cobalt-iron-boron (CoFeB) layer, a ruthenium (Ru) layer and a cobalt-iron (CoFe) layer. In addition, the free layer 110 may also include multiple material layers including a cobalt-iron-boron (CoFeB) layer, a ruthenium (Ru) layer and a cobalt-iron (CoFe) layer. Further, the tunnel barrier layer 114 may be magnesium oxide (MgO).

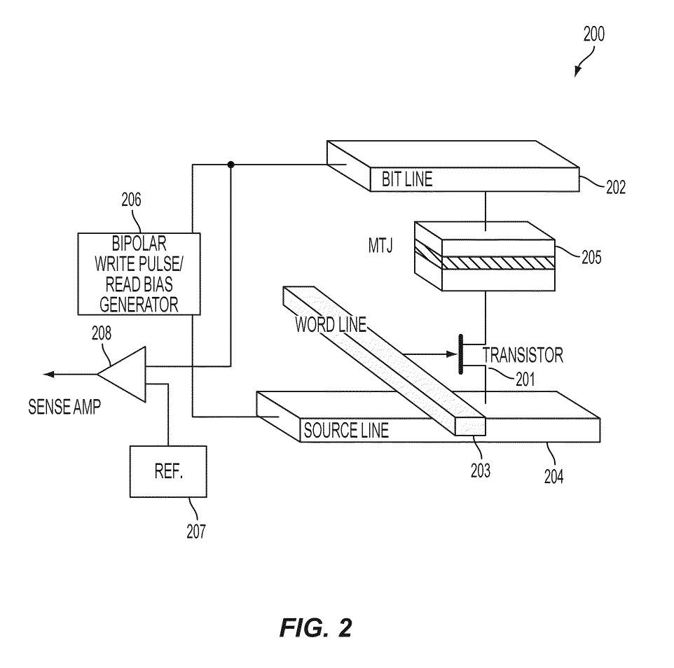

FIG. 2 illustrates a conventional STT-MRAM bit cell 200. The STT-MRAM bit cell 200 includes a magnetic tunnel junction (MTJ) storage element 205, a transistor 201, a bit line 202 and a word line 203. The MTJ storage element 205 is formed, for example, from at least two ferromagnetic layers (a pinned layer and a free layer), each of which can hold a magnetic field or polarization, separated by a thin non-magnetic insulating layer (tunneling barrier). Electrons from the two ferromagnetic layers can penetrate through the tunneling barrier due to a tunneling effect under a bias voltage applied to the ferromagnetic layers. The magnetic polarization of the free layer can be reversed so that the polarity of the pinned layer and the free layer are either substantially aligned or opposite. The resistance of the electrical path through the MTJ varies depending on the alignment of the polarizations of the pinned and free layers. This variance in resistance may program and read the bit cell 200. The STT-MRAM bit cell 200 also includes a source line 204, a sense amplifier 208, read/write circuitry 206 and a bit line reference 207.

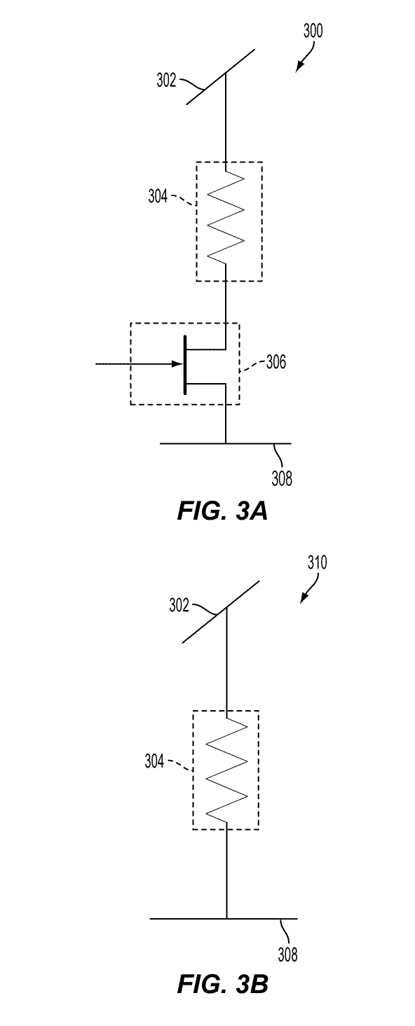

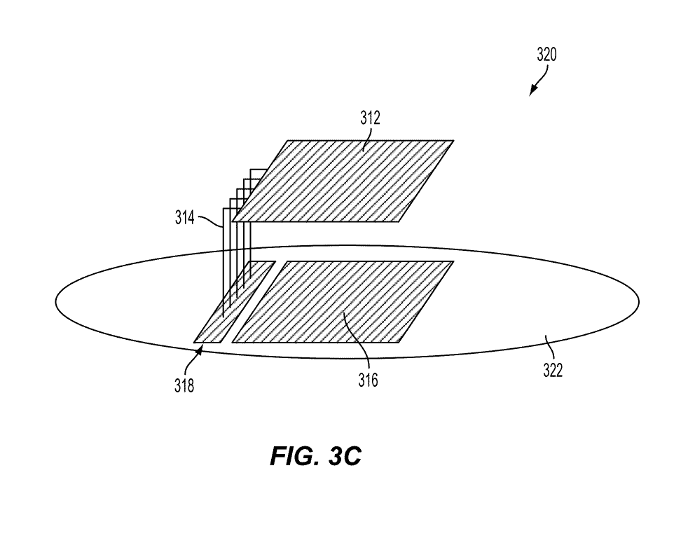

FIG. 3A is a schematic view of a 1T1R bit cell 300 according to an aspect of the present disclosure. The 1T1R bit cell 300 includes a first terminal 302, a resistive element 304, a switching element 306, and a second terminal 308. The first terminal 302 and the second terminal 308 couple to other portions of a memory array that includes the 1T1R bit cell 300. The first terminal 302 and the second terminal 308 may be orthogonal to one another. The resistive element 304 can be a resistor, MTJ, or may be a resistive memory element such as a resistive random access memory (RRAM) element or a phase change memory (PCM) element. The switching element 306 may be a transistor, a diode, or any element that allows switching and selection of the resistive element 304 for interconnection within the memory array. The switching element 306 in the 1T1R bitcell may be fabricated on single-crystal semiconductor material in order to have very good current control capability. This good current control capability enables read and write operations when multiple 1T1R bit cells 300 are arranged within a larger memory array.

The switching element 306 of the 1T1R bit cell 300 is usually a semiconductor device that involves more chip area for fabrication. As a result, the 1T1R bit cell 300 generally occupies more space due to the switching element 306. Thus, in the aggregate, and due to this higher chip area, the 1T1R bit cell 300 generally exhibits lower density. The switching element 306, however, enables faster access to any location of the memory array, which leads to higher performance. Therefore, a memory array that includes the 1T1R bit cell 300 exhibit higher performance, while exhibiting lower density and consuming a larger chip area.

FIG. 3B is a schematic view of a 0T1R bit cell 310 according to an aspect of the present disclosure. A memory array of the 0T1R bit cell 310 may be referred to as a cross-point array. The 0T1R bit cell 310 includes a first terminal 302, a resistive element 304, and a second terminal 308. The first terminal 302, the second terminal 308 and the resistive element 304 are all similar to the corresponding components described in FIG. 3A for the 1T1R bit cell 300. In contrast to the 1T1R bit cell 300 of FIG. 3A, the 0T1R bit cell 310 does not include the switching element 306 fabricated in single-crystal semiconductor material. Many 0T1R memory technologies also currently try to use thin-film devices to improve performance.

Optionally, the 0T1R bit cell 310 may also have a switching element (not shown) fabricated from a poly-crystalline or amorphous material. The switching element can be a thin-film-transistor made with poly-crystalline silicon. The switching element can also improve the performance of the 0T1R bit cell 310 as compared with the 0T1R bit cell 310 having no switching element. Nevertheless, the switching element may not have a good current control capability due to the large density of crystal defects inherent in its poly-crystalline or amorphous material. Therefore, even a 0T1R bit cell with a switching element cannot achieve as high a performance as the 1T1R bit cell 300. The switching element can also be fabricated above one or several interconnect levels, thereby not requiring electrical coupling to a single-crystal semiconductor substrate. Therefore, the space and the chip area consumed by the 0T1R bit cell 310 are significantly reduced. The 0T1R bit cell 310 also contains a resistive element 304. When current is applied to the 0T1R bit cell 310, the resistive element 304 exhibits a non-linear hysteresis-like curve or memory effect. That is, the switching element has a non-linear relationship between current and voltage.

Because the 0T1R bit cell 310 consumes significantly less chip area than a 1T1R bit cell 300, 0T1R bit cells 310 can provide an increased density when arranged in a larger memory array. The 0T1R bit cells 310 may exhibit a substantial density increase (e.g., a five to ten times increase, or 5-10×) when compared to the 1T1R bit cell 300. The 0T1R bit cell 310 also typically exhibits much lower performance when compared with the 1T1R bit cell 300, because the signals through a memory array, including multiple ones of the 0T1R bit cell 310, become diluted by the large network of resistors that disperse the collective flow of current. The 0T1R bit cell 310 also suffers a substantial reduced performance (e.g., ten to one-hundred time, or 10-100×) when compared to the 1T1R bit cell 300.

In one configuration, each 1T1R bit cell 300 includes a single-crystal semiconductor device directly coupled to a resistor. The single-crystal semiconductor device can be the switching element 306 and the resistor can be the resistive element 304 of the 1T1R bit cell 300. In one configuration, each 0T1R bit cell 310 includes a resistor. The resistor can be the resistive element 304 of the 0T1R bit cell 310. Each 0T1R bit cell 310 may also include instead of, or in addition to the resistor, a poly-crystalline or amorphous device having a non-linear relationship between current and voltage. The poly-crystalline or amorphous device can also be the resistive element 304 of the 0T1R bit cell 310, or a switching element that is not shown in FIG. 3B.

FIG. 3C is a 3D view of a resistive memory device 320 according to one aspect of the present disclosure. The resistive memory device 320 includes a 0T1R memory array 312, interconnects 314, peripheral circuitry 318, a 1T1R memory array 316 and a semiconductor die 322. The 1T1R memory array 316 is made up of multiple ones of the 1T1R bit cell 300. The 1T1R memory array 316 may include high performance access transistors in each 1T1R bit cell 300 to improve memory performance. The peripheral circuitry 318 is also a part of, or directly coupled to, the 1T1R memory array 316.

The 0T1R memory array 312 is made up of 0T1R bit cells 310. In this configuration, the 0T1R memory array 312 is a cross-point resistive memory that is implemented in a back-end-of-the-line (BEOL) interconnect level. The 0T1R memory array 312, however, generally exhibits slower performance, while providing higher density within a reduced chip area when compared to the 1T1R memory array 316.

According to one aspect of the present disclosure, the 0T1R memory array 312 can be placed over and coupled to the 1T1R memory array 316 via the peripheral circuitry 318 and the interconnects 314, as shown in FIG. 3C. The configuration shown in FIG. 3C improves performance, increases density, saves on chip area and strengthens the security of data storage for the resistive memory device 320. Because the individual 0T1R bit cells 310 in the 0T1R memory array 312 consume a relatively small chip area, they can be combined with the 1T1R bit cells 300 of the 1T1R memory array 316 without a substantial increases in the overall chip area. Furthermore, the resistive element 304 in each 0T1R bit cell 310 of the 0T1R memory array 312 and the resistive element 304 in each 1T1R bit cell 300 of the 1T1R memory array 316 can be configured differently to achieve improvements in performance and data storage security as well as reductions in chip area.

To improve performance, the resistive element 304 for each 1T1R bit cell 300 of the 1T1R memory array 316 can be a different resistive element than the resistive element 304 for each 0T1R bit cell 310 of the 0T1R memory array 312. For instance, the resistive element 304 in each 1T1R bit cell 300 of the 1T1R memory array 316 can be a high performance resistive device such as a spin transfer torque magnetoresistive random access memory (STT-MRAM). On the other hand, the resistive element 304 in each 0T1R bit cell 310 of the 0T1R memory array 312 can be a lower performance but smaller and higher density resistor. For example, the resistive element 304 may be a resistive random access memory (RRAM) device, a phase change memory (PCM) device, such as phase change random access memory (PCRAM), or other like memory device.

The resistance change across a 1T1R bit cell 300 of the 1T1R memory array 316 can be low to medium, for example, a 100% change or a change by a factor of two, because the 1T1R bit cell 300 already has a switching element 306 that provides the current isolation for performing read and write operations. Therefore, a high resistance change is not specified for performing the read and write operations. The specified resistance change for the 0T1R bit cell 310 of the OT memory array 312 may be much larger, for example, a 1000% change or a change by a factor of ten, in order to perform read and write operations. Because PCMs and RRAMs exhibit resistance changes by a factor of ten (10) to one hundred (100), they may be used for the 0T1R bit cell 310. Furthermore, the 0T1R bit cell 310 is easier to fabricate than the 1T1R bit cell 300 due to the reduced number of components of the 0T1R bit cell 310.

In one configuration, RRAMs in the 0T1R memory array 312 can be arranged on and coupled to MRAMs in the 1T1R memory array 316 because RRAMs do not involve silicon fabrication. Therefore, the overall chip area of the resistive memory device 320 is not increased or just slightly increased. The types of resistive elements 304 for each 1T1R bit cell 300 and each 0T1R bit cell 310 can be customized to provide a combination that yields improved perform for the resistive memory device 320.

In this arrangement, a peripheral circuitry 318 includes sense amplifiers for read operations, write drivers for write operations and decoders for both the read and write operations. The 0T1R memory array 312 is coupled by interconnects 314 to the peripheral circuitry 318. The 0T1R memory array 312 is therefore coupled to the various sense amplifiers, write drivers, and decoders of the peripheral circuitry 318.

The 1T1R memory array 316 and the 0T1R memory array 312 may be susceptible to different attacks. For example, MRAMs and STT-MRAMs are susceptible to strong magnetic fields, which may wipe the contents of resistive memory device 320, and PCMs may be susceptible to high temperature excursions or variations. Using an arrangement of different types of memory elements within a single device (e.g., MRAM, RRAM, PCM, PCRAM, STT-MRAM) may prevent the loss of data stored in resistive memory device 320 due to a single attack mechanism. Protection of critical data stored in a memory device is improved if a combination of different memory elements constructs the memory device.

A number of advantages are associated with the use of different memory elements to construct a memory device. For example, a micro-controller unit (MCU) including a MRAM-RRAM stack as shown in FIG. 3C can exhibit improved security. In this arrangement, two copies of critical data are stored in the MRAM and the RRAM. By storing critical data in two different types of memories within a single memory device, that memory device is more resilient to high magnetic fields or other denial of service (DoS) attacks as well as memory erasure due to different temperature sensitivities.

Furthermore, lower level SRAMs/MRAMs can be caches/buffers for RRAM storage. This approach leads to a reduction in chip area and manufacturing costs as compared to conventional embedded non-volatile memories (eNVM). That is, if low-level, high performance SRAM/MRAM bit cells are buffers for the 0T1R storage layer, then the space of the device is reduced while maintaining adequate performance for the overall memory system of the chip.

In one configuration, the 0T1R memory array 312 can be arranged within a footprint of the 1T1R memory array 316. In one configuration, the 0T1R memory array 312 and the 1T1R memory array 316 are integrated within different back-end-of-line (BEOL) interconnect layers. In this arrangement, the 0T1R memory array 312 is stacked on the 1T1R memory array 316. The 0T1R memory array 312 and the 1T1R memory array 316 may include resistive random access memory (RRAM), phase change memory (PCM) or spin-transfer-torque magnetoresistive random access memory (STT-MRAM).

Although a stacking memory arrangement is described, different memory elements can be placed on different portions of the die, and do not have to be stacked on one another. It is also generally more advantageous to place all associated memories in the portion of a die, and have data buses and other couplings flow out from that portion of the die. This practice may be followed because the silicon circuitry at the edge of a memory array is aligned with the pitch of the memory. Thus, it may be hard to find regular space on dies that implement random logic.

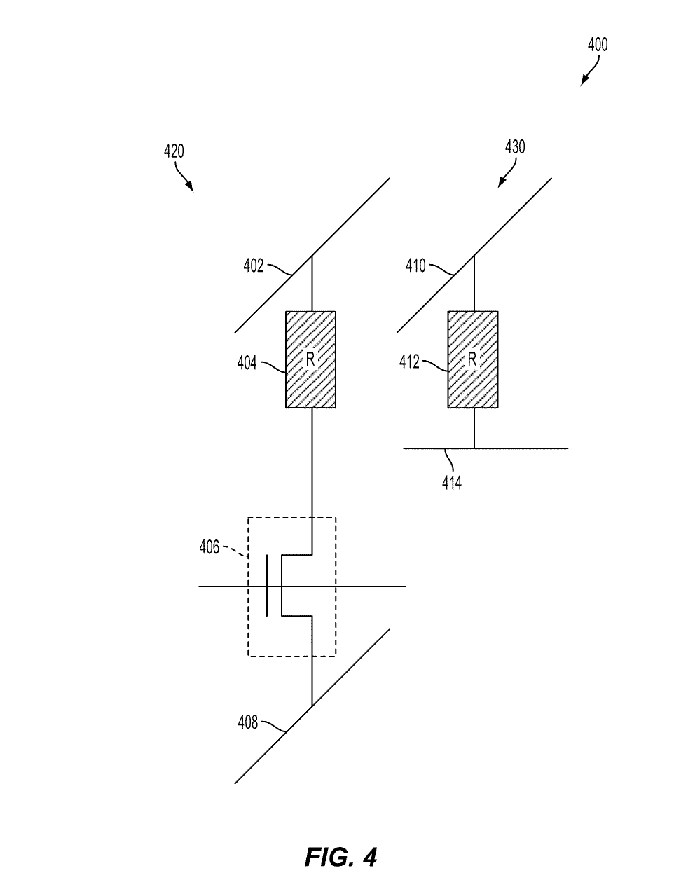

FIG. 4 is a schematic view of a resistive memory device 400 according to one aspect of the present disclosure. The resistive memory device 400 is an example of a combined bit cell approach that fabricates both a 1T1R bit cell 420 (similar to the 1T1R bit cell 300) and a 0T1R bit cell 430 (similar to the 0T1R bit cell 310) together in the same manufacturing steps. The resistive memory device 400 includes the 1T1R bit cell 420 and the 0T1R bit cell 430. The 1T1R bit cell 420 includes a first terminal 402, a second terminal 408, a first resistive element 404 and a switching element 406. The 0T1R bit cell 430 includes a third terminal 410, a fourth terminal 414, and a second resistive element 412. The components in FIG. 4 are similar to the components in FIGS. 3A-3B. In contrast to FIGS. 3A-3B, the components shown in FIG. 4 are located within the same resistive memory device 400.

The first resistive element 404 and the second resistive element 412 can be any resistor with multiple states, for example a RRAM element, a conductive-bridge-RAM (CBRAM) element, a phase change memory (PCM) element, a magnetic random access memory (MRAM) magnetic tunnel junction (MTJ) or a spin transfer torque magnetoresistive random access memory (STT-MRAM). The switching element 406 may be a transistor, a diode, or any element that allows the switching and selection of the first resistive element 404 within the memory array to perform read and write memory operations. The first terminal 402 and the second terminal 408 can be orthogonal to each other, and the third terminal 410 and the fourth terminal 414 can be orthogonal to each other as well. In addition, the first resistive element 404 and the second resistive element 412 can be the same. The first resistive element 404 and the second resistive element 412 can also be different. The 0T1R bit cell 430 can also be arranged within a footprint of the 1T1R bit cell 420.

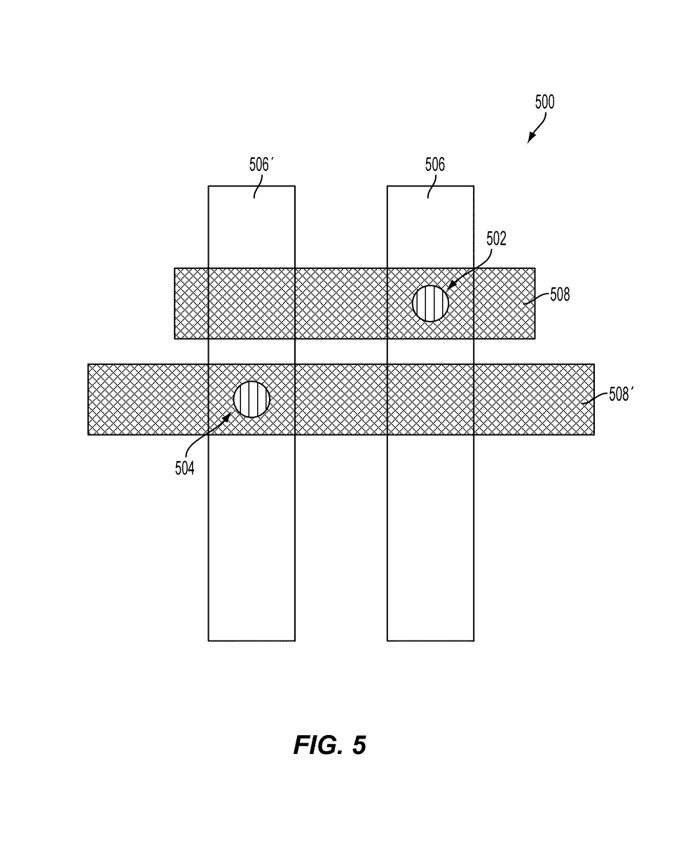

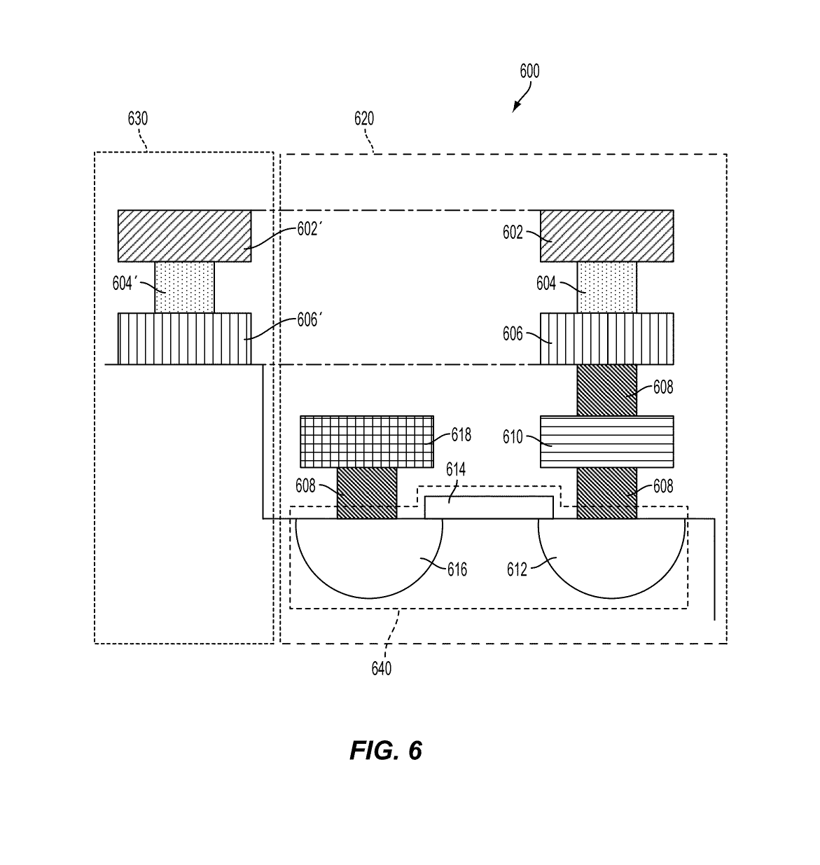

FIG. 5 is a layout view of a resistive memory device 500 according to one aspect of the present disclosure. The resistive memory device 500 may correspond to the resistive memory device 400 shown in FIG. 4. The resistive memory device 500 includes a first terminal 506, a second terminal 508, a 1T1R bit cell 504, a third terminal 506′, a fourth terminal 508′ and a 0T1R bit cell 502. As shown in the layout view of FIG. 5, the first terminal 506 and the second terminal 508 are orthogonal to each other, and meet at an intersection to form the 1T1R bit cell 502. The third terminal 506′ and the fourth terminal 508′ are also orthogonal to each other, and meet at an intersection to form the 0T1R bit cell 504. The second terminal 508 may be coupled to the switching element (not shown) of the 1T1R bit cell 502. The first terminal 506 and the third terminal 506′ can be parallel to one another and share the same conductive material layer (e.g., a first conductive material layer). In this arrangement, the second terminal 508 and the fourth terminal 508′ are also parallel to one another and share the same conductive material layer (e.g., a second conductive material layer). The first conductive material layer is different than the second conductive material layer. This arrangement is further illustrated in FIG. 6.

FIG. 6 is a cross-sectional view of a resistive memory device 600 according to one aspect of the present disclosure. The resistive memory device 600 corresponds to the resistive memory device 500 shown in FIG. 5 and the resistive memory device 400 shown in FIG. 4. The resistive memory device 600 includes a 1T1R bit cell 620 and a 0T1R bit cell 630. The 1T1R bit cell 620 includes a first terminal 602, a first resistive element 604, a second terminal 606, vias 608, a fifth terminal 610, a sixth terminal 618, and a switching element 640. The switching element 640 includes a gate 614, a first terminal 612 and a second terminal 616. The 0T1R bit cell 630 includes a third terminal 602′, a second resistive element 604′ and a fourth terminal 606′.

The first terminal 602 and the third terminal 602′ are at the same conductive interconnect level (e.g., Mₓ). The first terminal 602 and the third terminal 602′ are also parallel to one another and extend in the same direction. The second terminal 606 and the fourth terminal 606′ are at the same conductive interconnect level (e.g., Mₓ₋₁). The second terminal 606 and the fourth terminal 606′ are also parallel to one another and extend in the same direction. The fifth terminal 610 is at a different conductive interconnect level than Mₓ and Mₓ₋₁, (e.g., Mₓ₋₂). The sixth terminal 618 can be at any of the conductive interconnect levels (e.g., Mₓ, Mₓ₋₁, or Mₓ₋₂). The first terminal 602 and the sixth terminal 618 can be orthogonal to one another. In this configuration, the first terminal 602 is orthogonal to the second terminal 606, and the third terminal 602′ is orthogonal to the fourth terminal 606′. The various terminals may be fabricated with a conductive (e.g., metal) island design rule, which mandates that the wires have a certain minimum size and width. This conductive island design rule is one of the reasons why the 1T1R bit cell 620 consumes a larger cell area due to the reduced density. In addition, the 1T1R bit cell 620 also contains the switching element 640, which is shown as a transistor in FIG. 6.

According to this approach, the first resistive element 604 of the 1T1R bit cell 620 is to be fabricated at the same level and possibly at the same time, or in the same fabrication step, as the second resistive element 604′ of the 0T1R bit cell 630. The 0T1R bit cell 630 can also be arranged within a footprint of the 1T1R bit cell 620. The same level is denoted by the dotted lines extending from the 0T1R bit cell 630 to the 1T1R bit cell 620. The 0T1R bit cell 630 is also known as the cross-point of the resistive memory device 600. The impact on the overall chip area or chip size from the addition of the third terminal 602′, the second resistive element 604′ and the fourth terminal 606′ of the second resistive element 604′ is minimal. The first resistive element 604 and the second resistive element 604′ may be the same. In addition, the first resistive element 604 and the second resistive element 604′ may be an MTJ device (MRAM), a RRAM device, a PCRAM device (PCM), or a STT-MRAM device such as a perpendicular MTJ (pMTJ).

The first terminal 602, the first resistive element 604 and the second terminal 606 of the 1T1R bit cell 620 may be fabricated in substantially similar conditions (e.g., same time, same fabrication step, same order, same level, etc.) as the third terminal 602′, the second resistive element 604′ and the fourth terminal 606′ of the 0T1R bit cell 630. The components fabricated in each of the different bit cells may differ a bit in terms of size or other properties, but they may be substantially similar if not the same.

Electrically, the 1T1R bit cell 620 and the 0T1R bit cell 630 may be two separate arrays because each cell may use its own write drivers, sense amplifiers and other assorted circuitry. For example, in a one-megabit array (e.g., 1024 bit lines and 1024 wordlines) a one megabit arrangement of the faster 1T1R bit cell 620 array and a one megabit arrangement of the slower 0T1R bit cell 630 array may be provided.

The bit cell size of this approach may be slightly larger than the approach described in FIGS. 3A-3C because of the size of the switching element 640 (e.g., transistor) and potentially wider conductive island design rules or larger wires. This approach makes use of the unused space found in typical 1T1R bit cells due to space consumed by the transistors. Nevertheless, performance is not compromised because minimum conductive interconnect widths are not used, which affects the resistance. As a result, minimum allowed conductive interconnect widths can still be used to design the 0T1R bit cell without affecting the performance or the overall cell area.

The above-described approach provides the advantage of a single memory chip that contains both dense, rarely accessed storage memory (0T1R bit cells) together with fast memory (1T1R bit cells) to buffer the slower memory and to instantly run applications, for example. This combined single memory chip device is able to achieve both goals instead of having to use both a flash memory and a dynamic random access memory (DRAM), for example.

For the first approach described in FIGS. 3A-3C, the 0T1R bit cell can use one memory technology (e.g., MTJ) and the 1T1R bit cell can use another memory technology (e.g., RRAM) in the same device. In the approach described above with reference to FIGS. 4, 5 and 6, the two memory devices (resistive elements) of the 0T1R bit cell and the 1T1R bit cell can be fabricated together at the same time and can be the same type of memory element. This leads to lower manufacturing costs and a more practical and efficient fabrication process when compared to the first approach. For the first approach, two potentially different memory technologies are involved, whereas for the second approach, only one memory technology is manufactured.

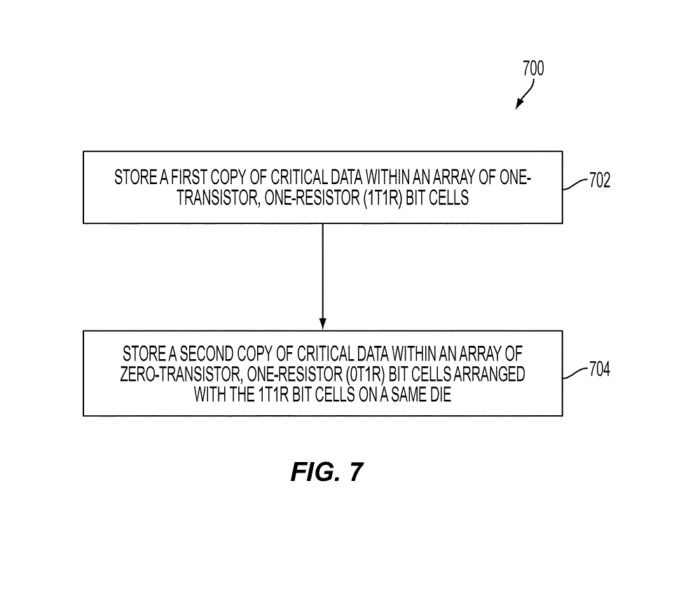

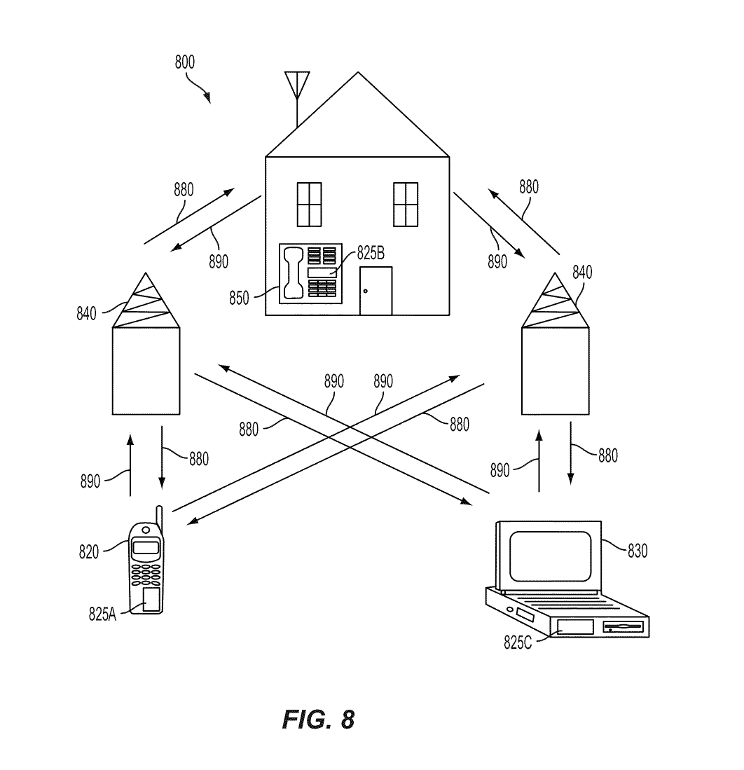

FIG. 7 is a process flow diagram illustrating a method 700 of storing data within a resistive memory array according to aspects of the present disclosure. In block 702, a first copy of critical data is stored within an array of one-transistor, one-resistor (1T1R) bit cells. In block 704, a second copy of critical data is stored within an array of zero-transistor, one-resistor (0T1R) bit cells arranged with the 1T1R bit cells on a same die.

In one configuration, the method 700 includes stacking the array of 0T1R bit cells on the array of 1T1R bit cells. In another configuration, the method 700 includes disposing a 0T1R bit cell within a footprint of a 1T1R bit cell. In another configuration, the method 700 includes integrating the array of 0T1R bit cells and the array of 1T1R bit cells within a back-end-of-line (BEOL) interconnect layer. In another configuration, the method 700 includes fabricating a first resistive element of the array of 1T1R bit cells and a second resistive element of the array of OT bit cells at the same time and on the same level. The first resistive element and the second resistive element are the same.

In one configuration, a method is provided for caching data within an array of 1T1R bit cells for an array of 0T1R bit cells arranged with 1T1R bit cells on a same die. In another configuration, the method includes using lower level static random access memory (SRAM) or magnetic random access memory (MRAM) as a cache-buffer for storage. In another configuration, the method includes disposing a 0T1R bit cell within a footprint of a 1T1R bit cell. In yet another configuration, the method includes integrating the array of 0T1R bit cells and the array of 1T1R bit cells within back-end-of-line (BEOL) interconnect layers. In another configuration, the method includes fabricating a first resistive element of the array of 1T1R bit cells and a second resistive element of the array of 0T1R bit cells at the same time and on the same level. The first resistive element and the second resistive element are the same.

According to one aspect of the present disclosure, a resistive memory array includes an array of one-transistor, one-resistor (1T1R) bit cells on a means for supporting and an array of zero-transistor, one resistor (0T1R) bit cells arranged with the array of 1T1R bit cells on the same supporting means. In one configuration, the supporting means is the semiconductor die 322. In another configuration, the aforementioned means may be any material or any layer configured to perform the functions recited by the aforementioned means. Although specific means have been set forth, it will be appreciated by those skilled in the art that not all of the disclosed means are specified for practicing the disclosed configurations. Moreover, certain well known means have not been described, to maintain focus on the disclosure.

In one configuration, the conductive material for the various conductive layers such as the various wires and/or vias are copper (Cu), or other conductive materials with high conductivity. Alternatively, the conductive material may include copper (Cu), silver (Ag), annealed copper (Cu), gold (Au), aluminum (Al), calcium (Ca), tungsten (W), zinc (Zn), nickel (Ni), lithium (Li) or iron (Fe). The aforementioned conductive material layers may also be deposited by electroplating, chemical vapor deposition (CVD), physical vapor deposition (PVD), sputtering, or evaporation.

FIG. 8 is a block diagram showing an exemplary wireless communication system 800 in which an aspect of the disclosure may be advantageously employed. For purposes of illustration, FIG. 8 shows three remote units 820, 830, and 850 and two base stations 840. It will be recognized that wireless communication systems may have many more remote units and base stations. Remote units 820, 830, and 850 include IC devices 825A, 825C and 825B that include the disclosed resistive memory device. It will be recognized that other devices may also include the disclosed resistive memory device, such as the base stations, switching devices, and network equipment. FIG. 8 shows forward link signals 880 from the base station 840 to the remote units 820, 830, and 850 and reverse link signals 890 from the remote units 820, 830, and 850 to base stations 840.

In FIG. 8, remote unit 820 is shown as a mobile telephone, remote unit 830 is shown as a portable computer, and remote unit 850 is shown as a fixed location remote unit in a wireless local loop system. For example, the remote unit may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as meter reading equipment, or other devices that store or retrieve data or computer instructions, or combinations thereof. Although FIG. 8 illustrates remote units according to the teachings of the disclosure, the disclosure is not limited to these exemplary illustrated units. Aspects of the disclosure may be suitably employed in many devices, which include the disclosed resistive memory devices.

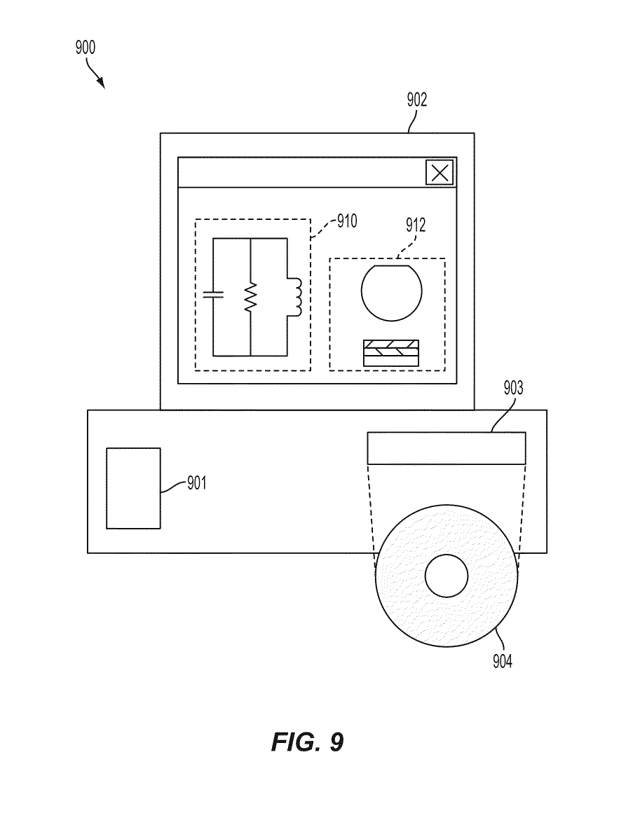

FIG. 9 is a block diagram illustrating a design workstation used for circuit, layout, and logic design of a semiconductor component, such as the resistive memory device disclosed above. A design workstation 900 includes a hard disk 901 containing operating system software, support files, and design software such as Cadence or OrCAD. The design workstation 900 also includes a display 902 to facilitate design of a circuit 910 or a semiconductor component 912 such as a resistive memory device. A storage medium 904 is provided for tangibly storing the circuit design 910 or the semiconductor component 912. The circuit design 910 or the semiconductor component 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may include specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit design 910 or the semiconductor component 912 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

It should be appreciated that memory devices including the MTJ storage elements described herein may be included within a mobile phone, portable computer, hand-held personal communication system (PCS) unit, portable data units such as personal data assistants (PDAs), GPS enabled devices, navigation devices, set top boxes, music players, video players, entertainment units, fixed location data units such as meter reading equipment, or any other device that stores or retrieves data or computer instructions, or any combination thereof. Accordingly, aspects of the disclosure may be suitably employed in any device, which includes active integrated circuitry including memory having MTJ storage elements as disclosed herein.

Further, it should be appreciated that various memory devices can include an array of MTJ storage elements as disclosed herein. Additionally, the MTJ storage elements may be used in various other applications, such as in logic circuits. Accordingly, although potions of the foregoing disclosure discuss the stand-alone MTJ storage element, it will be appreciated that various aspects can include devices into which the MTJ storage element is integrated.

Accordingly, aspects can include machine-readable media or computer-readable media embodying instructions which when executed by a processor transform the processor and any other cooperating elements into a machine for performing the functionalities described herein as provided for by the instructions.

While the foregoing disclosure shows illustrative aspects, it should be noted that various changes and modifications could be made herein without departing from the scope of the disclosure as defined by the appended claims. The functions, steps and/or actions of the method claims in accordance with the aspects described herein need not be performed in any particular order. Furthermore, although elements of the aspects may be described or claimed in the singular, the plural is contemplated unless limitation to the singular is explicitly stated.

Although the present disclosure and its advantages have been described in detail, it should be understood that various changes, substitutions and alterations can be made herein without departing from the technology of the disclosure as defined by the appended claims. For example, relational terms, such as “above,” “below,” “top” and “bottom” are used with respect to a substrate or electronic device. Of course, if the substrate or electronic device is inverted, above becomes below, top becomes bottom and vice versa. Additionally, if oriented sideways, the terms “above,” “below,” “top” and “bottom” may refer to sides of a substrate or electronic device, for example.

The word “exemplary” is used herein to mean “serving as an example, instance, or illustration.” Any aspect described herein as “exemplary” is not necessarily to be construed as preferred or advantageous over other aspects. Likewise, the term “aspects of the disclosure” does not require that all aspects of the disclosure include the discussed feature, advantage or mode of operation. The terminology used herein is for the purpose of describing particular aspects only and is not intended to be limiting of aspects of the disclosure.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A resistive memory array, comprising:
an array of one-transistor, one-resistor (1T1R) bit cells on a die; and
an array of zero-transistor, one-resistor (0T1R) bit cells arranged with the array of 1T1R bit cells on the same die.

2. The resistive memory array of claim 1, in which the array of 0T1R bit cells is stacked on the array of 1T1R bit cells.

3. The resistive memory array of claim 1, in which a 0T1R bit cell is disposed within a footprint of a 1T1R bit cell.

4. The resistive memory array of claim 1, in which the array of 0T1R bit cells and the array of 1T1R bit cells are integrated within different back-end-of-line (BEOL) interconnect layers.

5. The resistive memory array of claim 1,
in which the array of 0T1R bit cells comprises a resistive random access memory (RRAM), a phase change memory (PCM) or a spin-transfer-torque magnetoresistive random access memory (STT-MRAM), and
in which the array of 1T1R bit cells comprises RRAM, PCM or STT-MRAM.

6. The resistive memory array of claim 1, in which each 1T1R bit cell comprises a single-crystal semiconductor device directly coupled to a resistor.

7. The resistive memory array of claim 6, in which the resistor comprises a resistive random access memory (RRAM) element, a conductive-bridge-RAM (CBRAM) element, a phase change memory (PCM) element, a magnetic random access memory (MRAM) magnetic tunnel junction (MTJ) or a spin transfer torque magnetoresistive random access memory (STT-MRAM).

8. The resistive memory array of claim 1, in which each 0T1R bit cell comprises a resistor, the resistor comprising a resistive random access memory (RRAM) element, a conductive-bridge-RAM (CBRAM) element, a phase change memory (PCM) element, a magnetic random access memory (MRAM) magnetic tunnel junction (MTJ) or a spin transfer torque magnetoresistive random access memory (STT-MRAM).

9. The resistive memory array of claim 8, in which each 0T1R bit cell further comprises a poly-crystalline or amorphous device having a non-linear relationship between current and voltage.

10. The resistive memory array of claim 1 integrated into a mobile phone, a set top box, a music player, a video player, an entertainment unit, a navigation device, a computer, a hand-held personal communication systems (PCS) unit, a portable data unit, and/or a fixed location data unit.

11. A method of storing data within a hybrid resistive memory array, comprising:
storing a first copy of critical data within an array of one-transistor, one-resistor (1T1R) bit cells; and
storing a second copy of critical data within an array of zero-transistor, one-resistor (0T1R) bit cells arranged with the array of 1T1R bit cells on a same die.

12. The method of claim 11, further comprising:
caching data within the array of 1T1R bit cells for the array of 0T1R bit cells arranged with the array of 1T1R bit cells on the same die.

13. The method of claim 12, in which the caching comprises using lower level static random access memory (SRAM) or magnetic random access memory (MRAM) as a cache-buffer for storage.

14. The method of claim 11, further comprising integrating the hybrid resistive memory array into a mobile phone, a set top box, a music player, a video player, an entertainment unit, a navigation device, a computer, a hand-held personal communication systems (PCS) unit, a portable data unit, and/or a fixed location data unit.

15. A method of manufacturing a hybrid resistive memory array, comprising:
fabricating an array of one-transistor, one-resistor (1T1R) bit cells on a die; and
fabricating an array of zero-transistor, one-resistor (0T1R) bit cells arranged with the array of 1T1R bit cells on the same die.

16. The method of claim 15, further comprising stacking the array of 0T1R bit cells on the array of 1T1R bit cells.

17. The method of claim 15, further comprising disposing a 0T1R bit cell within a footprint of a 1T1R bit cell.

18. The method of claim 15, further comprising integrating the array of 0T1R bit cells and the array of 1T1R bit cells within different back-end-of-line (BEOL) interconnect layers.

19. The method of claim 15, further comprising fabricating a first resistive element of the array of 1T1R bit cells and a second resistive element of the array of 0T1R bit cells at the same time and on the same level, in which the first resistive element and the second resistive element are the same.

20. The method of claim 15, further comprising integrating the hybrid resistive memory array into a mobile phone, a set top box, a music player, a video player, an entertainment unit, a navigation device, a computer, a hand-held personal communication systems (PCS) unit, a portable data unit, and/or a fixed location data unit.
